(19) United States
(12) Patent Application Publication
(10) Pub. No.: US 2025/0015123 A1
(43) Pub. Date: Jan. 9, 2025

(54) ELECTRONIC COMPONENT, SEMICONDUCTOR DEVICE, AND METHOD OF MANUFACTURING SEMICONDUCTOR DEVICE

(71) Applicant: Sumitomo Electric Device Innovations, Inc., Yokohama-shi (JP)

(72) Inventor: Ikuo NAKASHIMA, Yokohama-shi (JP)

(73) Assignee: Sumitomo Electric Device Innovations, Inc., Yokohama-shi (JP)

(21) Appl. No.: 18/740,599

(22) Filed: Jun. 12, 2024

(30) Foreign Application Priority Data
Jul. 4, 2023 (JP) 2023-110035

(51) Int. Cl. H01L 23/367; H01L 23/522; H01L 23/64; H01L 23/00

(52) U.S. Cl. CPC H01L 28/24; H01L 23/367; H01L 23/5223; H01L 23/647; H01L 24/32; H01L 24/48; H01L 24/83; H01L 2224/32225; H01L 2224/48247; H01L 2224/83801; H01L 2924/13064; H01L 2924/19041; H01L 2924/19043

(57) ABSTRACT

An electronic component includes an insulator, a first resistor provided on the insulator, a first electrically insulating film provided on the first resistor to be in contact with the first resistor, and a first metal bonding material provided on the first electrically insulating film to be in contact with the first electrically insulating film and be in contact with a heat sink.

### REFERENCE TO RELATED APPLICATION

This application claims priority based on Japanese Patent Application No. 2023-110035 filed on Jul. 4, 2023, and the entire contents of the Japanese patent application are incorporated herein by reference.

### TECHNICAL FIELD

The present disclosure relates to an electronic component, a semiconductor device, and a method of manufacturing a semiconductor device.

### BACKGROUND ART

Patent literature (Japanese Unexamined Patent Application Publication No. S63-86904) discloses a technique related to a field effect transistor. This field effect transistor includes a plurality of power field effect transistor chips, capacitors for impedance matching provided corresponding to the power field effect transistor chips, an input matching circuit substrate, and an output matching circuit substrate in a package. In this field effect transistor, at least one of a gap in the a plurality of power field effect transistor chips or a gap between the power field effect transistor chip and an impedance matching capacitor is connected by a resistor film.

### SUMMARY OF THE INVENTION

An electronic component according to an embodiment of the present disclosure includes an insulator, a first resistor provided on the insulator, a first electrically insulating film provided on the first resistor to be in contact with the first resistor, and a first metal bonding material provided on the first electrically insulating film to be in contact with the first electrically insulating film and be in contact with a heat sink.

### BRIEF DESCRIPTION OF THE DRAWINGS

FIG. 1 is a plan view showing a semiconductor device according to a first embodiment of the present disclosure.

FIG. 2 is a cross-sectional view taken along line II-II shown in FIG. 1.

FIG. 3 is a cross-sectional view taken along line III-III shown in FIG. 1.

FIGS. 4A, 4B, and 4C are diagrams showing manufacturing processes of a semiconductor device according to the first embodiment.

FIG. 5 is a plan view showing a lead frame.

FIGS. 6A, 6B, and 6C are diagrams showing manufacturing processes of a semiconductor device according to the first embodiment.

FIGS. 7A, 7B, and 7C are diagrams showing manufacturing processes of a semiconductor device according to the first embodiment.

FIG. 8 is a plan view showing a semiconductor device according to a first modification.

FIG. 9 is a perspective view of a portion of a semiconductor device according to the first modification.

FIG. 10 is a plan view showing a semiconductor device according to a second modification.

FIGS. 11A and 11B are diagrams showing manufacturing processes of a semiconductor device according to the second modification.

FIGS. 12A and 12B are plan views showing a semiconductor device according to a third modification.

FIG. 13 is a cross-sectional view taken along line XIII-XIII shown in FIG. 12B.

FIG. 14 is a plan view showing a semiconductor device according to a fourth modification.

FIG. 15 is a plan view showing a semiconductor device according to a fifth modification.

FIGS. 16A, 16B, and 16C are diagrams showing manufacturing processes of a semiconductor device according to a fifth modification.

FIGS. 17A, 17B, and 17C are diagrams showing manufacturing processes of a semiconductor device according to the fifth modification.

FIGS. 18A, 18B, and 18C are diagrams showing manufacturing processes of a semiconductor device according to the fifth modification.

FIGS. 19A and 19B are plan views showing a semiconductor device according to a sixth modification.

FIG. 20 is a cross-sectional view taken along line XX-XX shown in FIG. 19B.

### DETAILED DESCRIPTION

### Problem to be Solved by Present Disclosure

For example, in an electronic component such as a semiconductor device, a circuit using a resistor is configured. In this circuit, the resistor consumes electric power, and thus heat is generated in the resistor. Thus, a base material made of, for example, alumina is used for heat release. However, when the power consumption in the resistor is large, the heat release is insufficient with the thermal conductivity of alumina. When the heat release is insufficient, the lifespan of the resistor is likely to be shortened due to heat generation.

An object of the present disclosure is to provide an electronic component, a semiconductor device, and a method for manufacturing a semiconductor device, in which the life of a resistor is less likely to be reduced.

### DESCRIPTION OF EMBODIMENTS OF PRESENT DISCLOSURE

Details of embodiments of the present disclosure will be first described in a list.

[1] An electronic component according to an embodiment of the present disclosure includes an insulator, a first resistor provided on the insulator, a first electrically insulating film provided on the first resistor to be in contact with the first resistor, and a first metal bonding material provided on the first electrically insulating film to be in contact with the first electrically insulating film and be in contact with a heat sink.

Since the first electrically insulating film is interposed between the first resistor and the first metal bonding material, even when the first metal bonding material is provided on the first electrically insulating film, insulation between the first resistor and the first metal bonding material is maintained. The heat generated in the first resistor is transmitted to the first electrically insulating film in contact with the first resistor, and then reaches the first metal bonding material in contact with the first electrically insulating film. The first metal bonding material is also in contact with the heat sink. Thus, heat generated in the first resistor is released to the heat sink via the first metal bonding material in addition to heat release to the insulator. Thus, it is possible to obtain an electronic component in which heat release efficiency is improved and the lifespan of the resistor is not easily reduced.

[2] In the electronic component according to [1], the insulator may be provided on the heat sink. The insulator is provided on the heat sink, and thus heat released from the resistor to the insulator is transferred to the heat sink. Thus, the heat released from the resistor is less likely to be accumulated in the insulator, and is more likely to be released to the heat sink. Thus, heat released efficiency through the insulator is improved.

[3] In the electronic component according to [1] or [2], the first electrically insulating film may contain at least one of glass and ceramic. Since the first electrically insulating film is made of glass or ceramic, the first electrically insulating film can be applied locally. This makes it easy to apply the first electrically insulating film on the first resistor. In addition, since glass or ceramic generally has high heat resistance, it can withstand the heat from the melted first metal bonding material.

[4] A semiconductor device according to an embodiment of the present disclosure may be a semiconductor device in which the electronic component according to [1] is mounted on the heat sink, and the semiconductor device may include a semiconductor chip provided on the heat sink, and a capacitor provided on the heat sink. The semiconductor chip is electrically connected to the capacitor and the first resistor through a wire. The current that has passed through the semiconductor chip and the capacitor is partially consumed by the first resistor, and the first resistor generates heat. Thus, by providing the first metal bonding material on the first resistor, heat can be efficiently dissipated.

[5] In the semiconductor device according to [4], the semiconductor chip may be a transistor. The first resistor may be a resistor for a low-frequency pass or for oscillation prevention. In general, in an amplifier such as a transistor, power consumption in a resistor is large. Thus, the first metal bonding material is provided on the first resistor of the semiconductor device. Heat generated in the first resistor is released to the insulator and is also released to the heat sink via the first metal bonding material. Thus, the heat release efficiency of the semiconductor device is improved.

[6] In the semiconductor device according to [4] or [5], the semiconductor chip may include a silicon carbide substrate. The first metal bonding material may be a silver paste.

[7] The semiconductor device according to any one of [4] to [6] may further include a second resistor provided on the insulator, a second electrically insulating film provided on the second resistor to be in contact with the second resistor, and a second metal bonding material provided on the second electrically insulating film to be in contact with the second electrically insulating film. The second resistor may have a resistance value differing from a resistance value of the first resistor. The circuit configuration can be easily changed by providing the second resistor having the resistance value different from that of the first resistor and changing the connection of the resistors in the semiconductor device.

[8] In the semiconductor device according to any one of [4] to [7], the insulator may be a frame body provided on the heat sink and having a cavity inside the frame body. The semiconductor chip and the capacitor may be disposed inside the cavity. The frame body and the heat sink may be members constituting a package of the semiconductor device. For heat dissipation, the insulator is provided in contact with the first resistor. The insulator is provided on the heat sink as the frame body of the package in the semiconductor device. In this way, the frame body also serves as the insulator, and thus the number of components mounted on the semiconductor device is reduced.

[9] In the semiconductor device according to [8], the frame body may have a side surface on an inner side of the cavity. The side surface may be provided with a half via. In the first metal bonding material, a portion between a portion in contact with the first electrically insulating film and a portion in contact with the heat sink may be accommodated in the half via. By the half via, the first metal bonding material can be more reliably guided to a desired position on the heat sink. Thus, the first metal bonding material can be applied to a desired position with high accuracy.

[10] A method of manufacturing a semiconductor device according to an embodiment of the present disclosure includes; preparing a frame body having a cavity inside the frame body and constituted by an insulator, the frame body being bonded on a heat sink; forming a resistor on the frame body; forming an electrically insulating film on the resistor to be in contact with the resistor; and dropping a metal bonding material to be in contact with the electrically insulating film and the heat sink.

Since the electrically insulating film is provided in contact with the resistor, the insulation of the resistor is maintained even when the metal bonding material is provided in contact with the electrically insulating film. The heat generated in the resistor is transmitted to the electrically insulating film in contact with the resistor, and then reaches the metal bonding material in contact with the electrically insulating film. The metal bonding material is also in contact with the heat sink. Thus, heat generated in the resistor is released to the heat sink via the metal bonding material in addition to the heat release to the insulator. Thus, it is possible to obtain a method of manufacturing the electronic component in which heat release efficiency is improved and the lifespan of the resistor is not easily reduced.

[11] The method of manufacturing the semiconductor device according to may further include mounting a semiconductor chip and a capacitor on the heat sink after the dropping. In the dropping, the metal bonding material may be applied to a region on the heat sink at which the semiconductor chip and the capacitor are to be mounted. The metal bonding material is applied and dropped, in the same process, on a portion of the heat sink on which the semiconductor chip and the capacitor are mounted and on the electrically insulating film. Thus, the number of processes is reduced and the working efficiency is improved.

### DETAILS OF EMBODIMENT OF PRESENT DISCLOSURE

Specific examples of the electronic component, the semiconductor device, and the manufacturing method of the semiconductor device of the present disclosure will be described below with reference to the drawings. It is noted that, the present invention is not limited to these examples, but is defined by the scope of the claims, and is intended to include all modifications within the meaning and scope equivalent to the scope of the claims. In the following description, the same elements are denoted by the same reference numerals in the description of the drawings, and the overlapping description will be omitted.

### First Embodiment

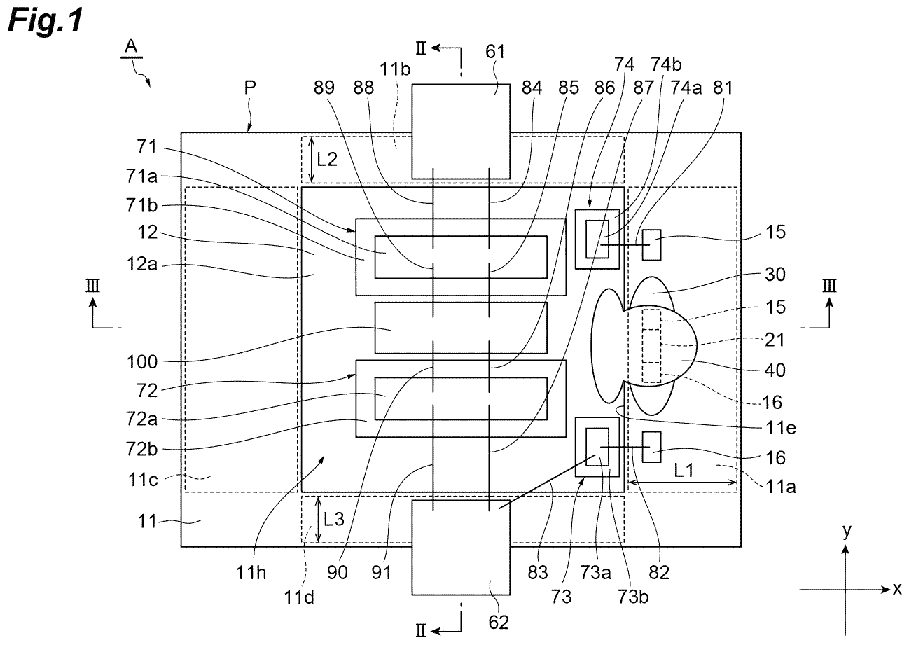

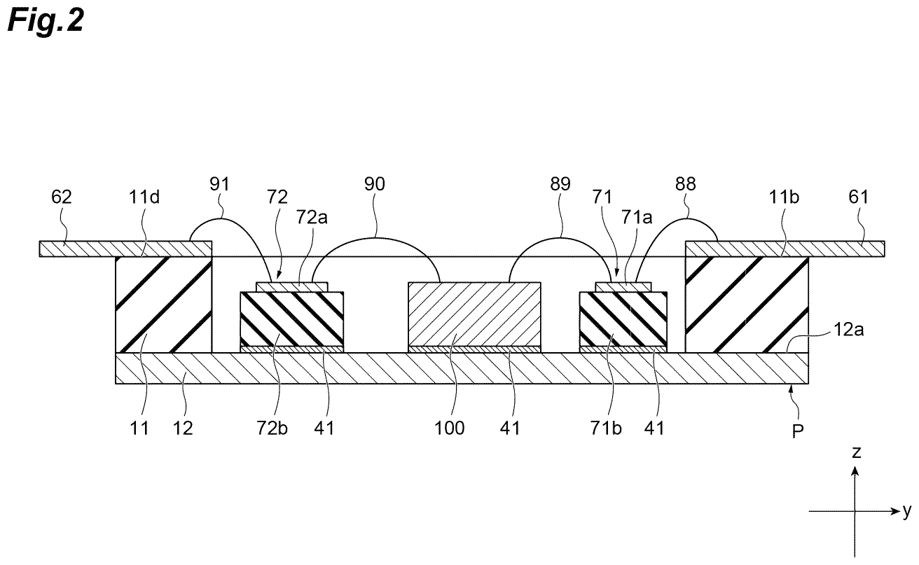

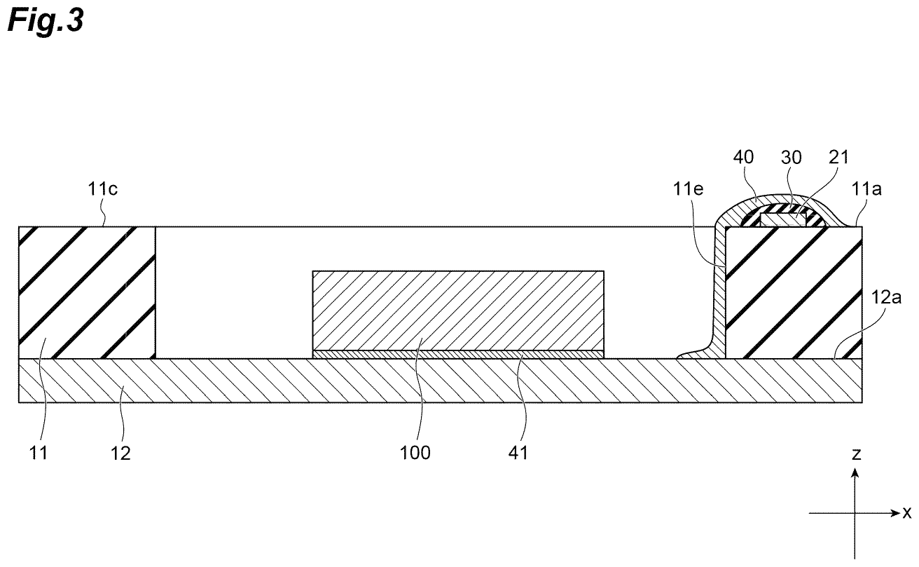

FIG. 1 is a plan view showing a semiconductor device A according to a first embodiment of the present disclosure. FIG. 2 is a cross-sectional view taken along line II-II shown in FIG. 1. FIG. 3 is a cross-sectional view taken along line III-III shown in FIG. 1. In each figure, an xyz orthogonal coordinate system is shown.

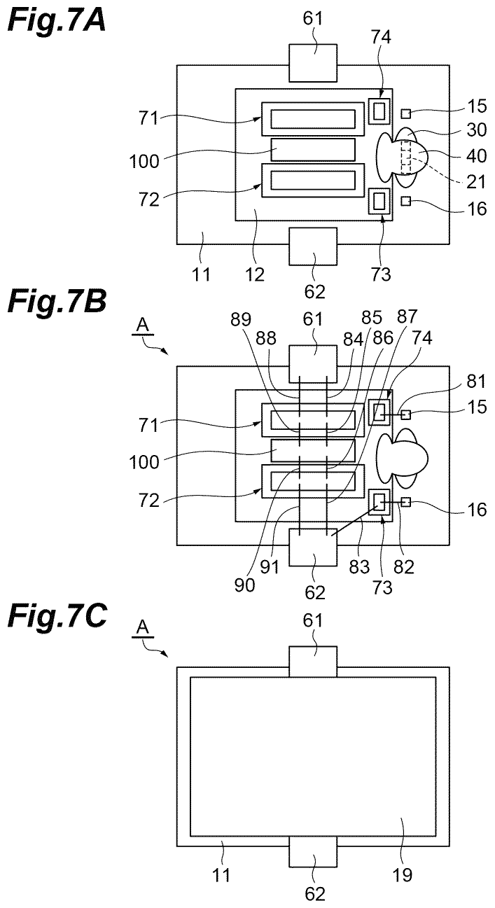

Semiconductor device A is an example of an electronic component of the present disclosure. Semiconductor device A includes a package P. Package P includes a stem 12, a frame body 11, and a lid 19 (refer to FIG. 7C). In other words, stem 12, frame body 11, and lid 19 are members constituting package P. Stem 12 is a plate-like body and has a rectangular shape in plan view. A cross section perpendicular to the direction in which stem 12 extends has a rectangular shape. Stem 12 has a surface 12a. Surface 12a is a surface of stem 12. Surface 12a faces in a direction perpendicular to the direction in which stem 12 extends. The material of stem 12 is a metal such as copper (Cu). Stem 12 functions as a heat sink. Stem 12 is set to a reference potential (ground potential).

Frame body 11 is an insulator fixed on surface 12a of stem 12. Frame body 11 has a rectangular frame shape in plan view, and has a cavity 11h inside thereof. The cavity 11h has a rectangular shape when viewed from the normal direction of surface 12a. Frame body 11 includes surfaces 11a to 11e. Surfaces 11a to 11d are surfaces of frame body 11 on the opposite side to stem 12, which face in a direction perpendicular to the direction in which frame body 11 extends. Surface 11a and surface 11c are arranged along the Y direction (the direction along the short side of frame body 11). Surface 11b and surface 11d are along the x direction (the direction along the long side of frame body 11). A gap L1 in the x direction between the outer edge and the inner edge of frame body 11 on surface 11a is larger than a gap L2 in the Y direction between the outer edge and the inner edge of frame body 11 on surface 11b. Gap L1 is larger than a gap L3 which is a gap in the Y direction between the outer edge and the inner edge of frame body 11 on surface 11d. Surface Ile is a side surface on the inner side of cavity 11h of frame body 11, and is a surface along the Y direction, continuous with surface 11a. A cross section perpendicular to the direction in which frame body 11 extends has a rectangular shape. The material of frame body 11 is, for example, ceramic such as alumina (Al₂O₃). The thermal conductivity of alumina is, for example, about 32 W/(m·K). Frame body 11 is formed by, for example, single-layer alumina.

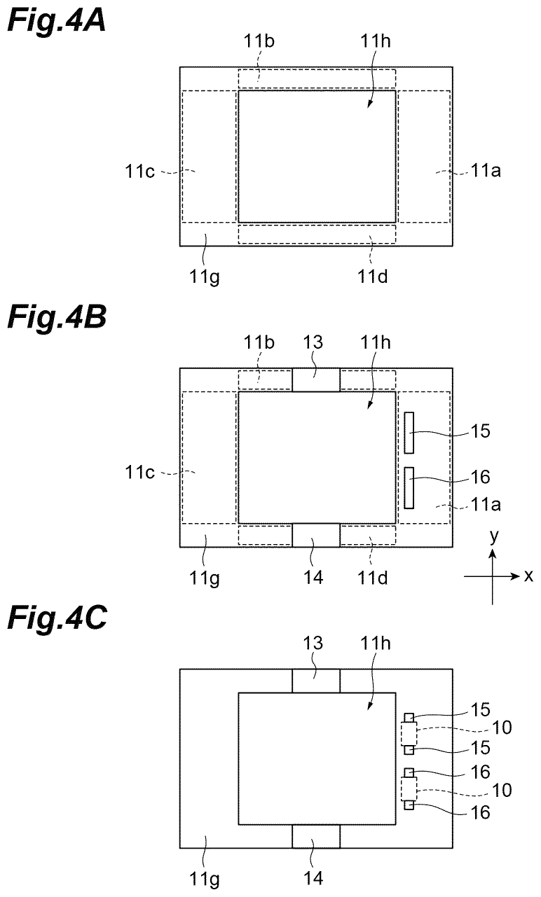

Semiconductor device A includes a terminal 61, a terminal 62, a resistor 21 (first resistor), a pattern 15, and a pattern 16. Terminal 61 is provided on the center portion of surface 11b. Terminal 62 is provided on the center portion of surface 11d. Terminal 61 and terminal 62 have a rectangular shape in plan view. Terminals 61 and 62 are conductive and plated with gold (Au). Terminal 61 is, for example, an input terminal. Terminal 62 is, for example, an output terminal. Resistor 21 is provided on the center portion of surface 11a, closer to the inner edge of frame body 11 than the outer edge of frame body 11, and in contact with surface 11a. Resistor 21 has a rectangular film shape. The material of resistor 21 is, for example, an alloy containing at least one conductor of silver (Ag), palladium (Pd), and platinum (Pt). Resistor 21 is a resistor for a low-frequency pass. Pattern 15 and pattern 16 are arranged along the Y direction on surface 11a to be in contact with surface 11a. Pattern 15 and pattern 16 are provided on both sides of resistor 21 in the Y direction with resistor 21 interposed therebetween and are in contact with resistor 21. Pattern 15 is disposed on terminal 61 side with respect to resistor 21, in other words, pattern 15 is disposed nearer to terminal 61 than resistor 21. Pattern 16 is disposed on terminal 62 side with respect to resistor 21, in other words, pattern 16 is disposed nearer to terminal 62 than resistor 21. Each center portion of pattern 15 and pattern 16 is covered with a ceramic coat 10 (refer to FIG. 4C). Only the end portion of each of pattern 15 and pattern 16 is exposed from ceramic coat 10. Pattern 15 and pattern 16 have rectangular film shapes. The material of each of patterns 15 and 16 is, for example, a metal such as tungsten (W), platinum (Pt), silver (Ag), or copper (Cu), or an alloy thereof. Pattern 15 and pattern 16 are plated with gold (Au).

Further, semiconductor device A includes a semiconductor chip 100, capacitors 71 to 74, and wires 81 to 91. Semiconductor chip 100 is provided on the center portion of surface 12a on the inside of cavity 11h of frame body 11. A rear surface of semiconductor chip 100 is conductively bonded to surface 12a of stem 12 via a metal bonding material 41. Semiconductor chip 100 is, for example, a transistor. When semiconductor chip 100 is, for example, a nitride semiconductor element, its substrate is, for example, a silicon carbide (SiC) substrate, a silicon (Si) substrate, a gallium nitride (GaN) substrate, or a sapphire (Al₂O₃) substrate. A semiconductor layer on the substrate includes a nitride semiconductor layer such as a gallium nitride layer, an aluminum gallium nitride (AlGaN) layer, and/or an indium gallium nitride (InGaN) layer. When the transistor is a gallium nitride high electron mobility transistor (GaN HEMT), the semiconductor layer includes a gallium nitride channel layer provided on the substrate and an aluminum gallium nitride barrier layer provided on the channel layer. When semiconductor chip 100 is, for example, a gallium arsenide (GaAs)-based semiconductor, the substrate is, for example, a gallium arsenide substrate. The semiconductor layer provided on the substrate includes an arsenide semiconductor layer such as a gallium arsenide layer, an aluminum gallium arsenide (AlGaAs) layer and/or an indium gallium arsenide (InGaAs) layer. Semiconductor chip 100 may be a silicon semiconductor such as a laterally diffused metal oxide semiconductor (LDMOS). Capacitors 71 to 74 are provided on surface 12a inside cavity 11h of frame body 11. Capacitor 71 and capacitor 72 are provided on both sides of semiconductor chip 100 in the Y direction, sandwiching semiconductor chip 100. Capacitor 71 is provided closer to terminal 61 with respect to semiconductor chip 100. Capacitor 72 is provided closer to terminal 62 with respect to semiconductor chip 100. Capacitor 73 and capacitor 74 are provided closer to resistor 21 with respect to semiconductor chip 100. Capacitor 73 is provided closer to terminal 62 with respect to semiconductor chip 100. Capacitor 74 is provided closer to terminal 61 with respect to semiconductor chip 100. Capacitor 71 is constituted by a metal film 71a, a ceramic block 71b, and stem 12. Capacitor 72 is constituted by a metal film 72a, a ceramic block 72b, and stem 12. Capacitor 73 is constituted by a metal film 73a, a ceramic block 73b, and stem 12. Capacitor 74 is constituted by a metal film 74a, a ceramic block 74b, and stem 12. Capacitor 71 and capacitor 72 function as a part of a matching circuit in semiconductor device A. Each rear surface of ceramic blocks 71b to 74b is bonded to surface 12a of stem 12 via metal bonding material 41. Wire 81 connects pattern 15 and metal film 74a of capacitor 74. Wire 82 connects pattern 16 and metal film 73a of capacitor 73. Wire 83 connects metal film 73a of capacitor 73 and terminal 62. Wire 84 and wire 88 connect terminal 61 and metal film 71a of capacitor 71. Wire 85 and wire 89 electrically connect metal film 71a of capacitor 71 and semiconductor chip 100. Wire 86 and wire 90 electrically connect semiconductor chip 100 and metal film 72a of capacitor 72. Wire 87 and wire 91 connect metal film 72a of capacitor 72 and terminal 62. Wires 81 to 91 are, for example, bonding wires.

Semiconductor device A functions as, for example, a high-frequency amplifier device. An input signal input to terminal 61 is input to semiconductor chip 100 through a matching circuit including capacitor 71. The signal amplified in semiconductor chip 100 is output from terminal 62 through a matching circuit including capacitor 72. In the circuit including resistor 21, capacitor 73, and capacitor 74, the low frequency component is suppressed. At this time, resistor 21 consumes electric power.

Semiconductor device A includes an electrically insulating film 30 (first electrically insulating film) and a metal bonding material 40 (first metal bonding material). Resistor 21 is coated with electrically insulating film 30. Electrically insulating film 30 covers entire resistor 21. Electrically insulating film 30 is in contact with resistor 21. Electrically insulating film 30 has an elliptical shape in plan view. The inner diameter of electrically insulating film 30 in the x direction is shorter than the inner diameter of electrically insulating film 30 in the Y direction. Electrically insulating film 30 is formed by solidifying a paste material. The material of electrically insulating film 30 is, for example, glass containing silicon (Si). The thermal conductivity of the glass is, for example, approximately 1 W/(m·K). Metal bonding material 40 is provided on electrically insulating film 30 and is in contact with electrically insulating film 30. In addition, metal bonding material 40 is also in contact with surface 11a. As shown in FIG. 3, a portion of metal bonding material 40 in contact with electrically insulating film 30 and surface 11a extends in the x direction. Metal bonding material 40 is also in contact with surface Ile, and a portion of metal bonding material 40 in contact with surface 11e extends in the z direction. Metal bonding material 40 is also in contact with surface 12a of stem 12, and a portion of metal bonding material 40 in contact with stem 12 extends in the x direction and the y direction. Metal bonding material 40 is continuously in contact with electrically insulating film 30, frame body 11, and stem 12. Metal bonding material 40 spreads in a semicircular shape in the x direction from the inner edge of frame body 11 on surface 11a. Metal bonding material 40 spreads in an elliptical shape in the x direction from the inner edge of frame body 11 on surface 12a. Metal bonding material 40 is made of a metal that melts at a temperature of, for example, 180° C. to 350° C. The material of metal bonding material 40 is, for example, silver paste or solder. The thermal conductivity of silver (Ag) is, for example, about 427 W/(m·K). The thermal conductivity of the Sn—Ag—Cu based solder is, for example, about 55 W/(m·K). The material of metal bonding material 40 may be the same as or different from the material of metal bonding material 41.

A method of manufacturing semiconductor device A according to the first embodiment of the present disclosure will be described with reference to FIGS. 4A, 4B, 4C, 5, 6A, 6B, 6C, 7A, 7B, and 7C. First, frame body 11 having cavity 11h on the inside and formed of an insulator is prepared. As shown in FIG. 4A, cavity 11h is provided on the center portion of a green sheet 11g made of ceramic before firing. Next, as shown in FIG. 4B, a pattern 13, a pattern 14, pattern 15, and pattern 16 are provided on green sheet 11g by pattern printing. Pattern 13 is a metal pattern and is disposed on the center portion of surface 11b. Pattern 14 is a metal pattern and is disposed on the center portion of surface 11d. The material of each of patterns 13 and 14 is a metal such as tungsten (W), platinum (Pt), silver (Ag), or copper (Cu), or an alloy thereof. Thereafter, as shown in of FIG. 4C, ceramic coat 10 is applied to the center portion of pattern 15 and the center portion of pattern 16. At this time, only the end portions of patterns 15 and 16 are exposed. Ceramic coat 10 is a paste material containing ceramic. Thereafter, green sheet 11g and ceramic coat 10 are fired to form frame body 11.

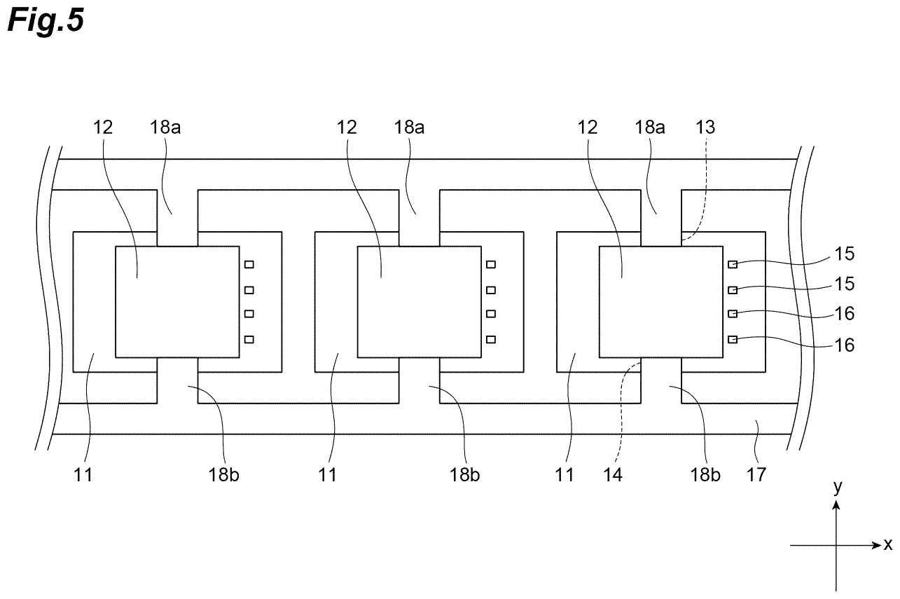

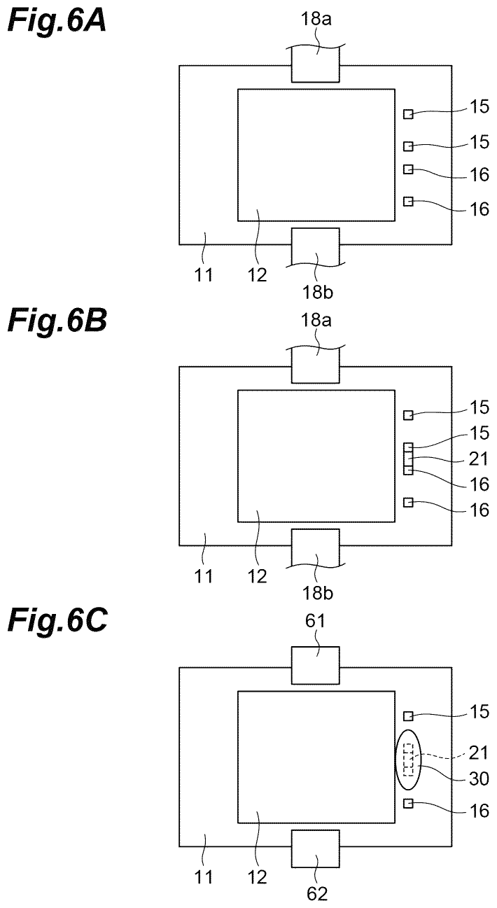

Next, a metal pattern (not shown) is formed on a rear surface of frame body 11. Thereafter, stem 12 is bonded to the rear surface of frame body 11. FIG. 5 is a plan view showing a lead frame 17. Lead frame 17 is arranged on frame body 11. Lead frame 17 has two portions that are located on both sides of frame body 11 in the Y direction with frame body 11 interposed therebetween. Lead frame 17 includes a tie bar 18a and a tie bar 18b. Tie bar 18a and tie bar 18b are located on both sides of frame body 11 in the Y direction. Tie bar 18a is brought into contact with pattern 13. Tie bar 18b is brought into contact with pattern 14. Then, as shown in FIG. 6A, tie bar 18a and pattern 13 are bonded and fixed to each other by a brazing material containing silver, copper, or an alloy thereof, for example. Similarly, tie bar 18b and pattern 14 are bonded and fixed to each other by a brazing material containing, for example, silver, copper, or an alloy thereof. Thereafter, stem 12, pattern 15, pattern 16, tie bar 18a, and tie bar 18b are plated with gold (Au). Subsequently, as shown in FIG. 6B, a film for resistor 21 connected to pattern 15 and pattern 16 is formed between pattern 15 and pattern 16 on frame body 11, and the film is fired together with frame body 11 to form resistor 21. Thereafter, as shown in FIG. 6C, electrically insulating film 30 in contact with resistor 21 is formed on resistor 21. Electrically insulating film 30 is provided on resistor 21 by, for example, printing of glass coating so as to cover entire resistor 21. Thereafter, the glass coating is fired together with frame body 11 to form electrically insulating film 30. Thereafter, tie bar 18a and tie bar 18b are cut off from the main body of lead frame 17. As a result, tie bar 18a becomes terminal 61, and tie bar 18b becomes terminal 62.

Next, metal bonding material 41 is applied to the region where semiconductor chip 100 and capacitors 71 to 74 are to be mounted, and at the same time, as shown in FIG. 7A, metal bonding material 40 is dropped so as to be in contact with electrically insulating film 30 and stem 12. The melting temperature of metal bonding material 40 is, for example, 180° C. to 350° C. Thereafter, semiconductor chip 100 and capacitors 71 to 74 are fixed and mounted on stem 12. Subsequently, as shown in FIG. 7B, wires 81 to 91 are provided. Finally, as shown in FIG. 7C, lid 19 is attached on frame body 11. Lid 19 has a plate shape.

The effects obtained from semiconductor device A and the manufacturing method of semiconductor device A having the above configuration will be described. Semiconductor device A consumes power in resistor 21, and thus heat is generated in resistor 21. In general, in an amplifier such as a transistor, power consumption in a resistor is large. Since resistor 21 is provided on frame body 11, heat generated in resistor 21 is released through frame body 11. However, when the power consumption in resistor 21 is large, the heat release is insufficient with the thermal conductivity of frame body 11. Thus, in semiconductor device A according to the first embodiment, electrically insulating film 30 and metal bonding material 40 are provided. Electrically insulating film 30 is interposed between resistor 21 and metal bonding material 40. Thus, even when metal bonding material 40 is provided on electrically insulating film 30, insulation between resistor 21 and metal bonding material 40 is maintained. Electrically insulating film 30 is sufficiently thin, and heat generated in resistor 21 is transmitted to electrically insulating film 30 in contact with resistor 21, and then reaches metal bonding material 40 in contact with electrically insulating film 30. Metal bonding material 40 is also in contact with stem 12. Thus, the heat generated in resistor 21 is released to stem 12 via metal bonding material 40 in addition to the heat releases to frame body 11. Thus, it is possible to obtain semiconductor device A and the manufacturing method of semiconductor device A in which the heat release efficiency is improved and the lifespan of resistor 21 is not easily reduced. In addition, in the same manufacturing process, metal bonding material 41 is applied to electrically insulating film 30 and to the portion of stem 12 on which semiconductor chip 100 and capacitors 71 to 74 are mounted. Thus, the manufacturing method of semiconductor device A can be obtained in which the number of processes is reduced and the working efficiency is improved.

Frame body 11 is provided on stem 12, and thus heat released from resistor 21 to frame body 11 is transmitted to stem 12. Thus, the heat released from resistor 21 is less likely to be accumulated in frame body 11, and is more likely to be released to stem 12. Thus, heat release efficiency through frame body 11 is improved.

The current passing from capacitor 73 to capacitor 74 passes through resistor 21, and resistor 21 generates heat. Thus, by providing metal bonding material 40 on resistor 21, heat can be efficiently released. Further, the insulator is provided in contact with resistor 21 for heat release. The insulator is provided on stem 12 as frame body 11 of the package in semiconductor device A. In this way, frame body 11 also serves as an insulator on which resistor 21 is mounted, and thus the number of components mounted on semiconductor device A is reduced.

As in the embodiment, electrically insulating film 30 may contain at least one of glass and ceramic. Electrically insulating film 30 is, for example, glass, and thus electrically insulating film 30 can be locally applied. This makes it easy to apply electrically insulating film 30 on resistor 21. In addition, since glass generally has high heat resistance, it can withstand the heat from melted metal bonding material 40.

### First Modification

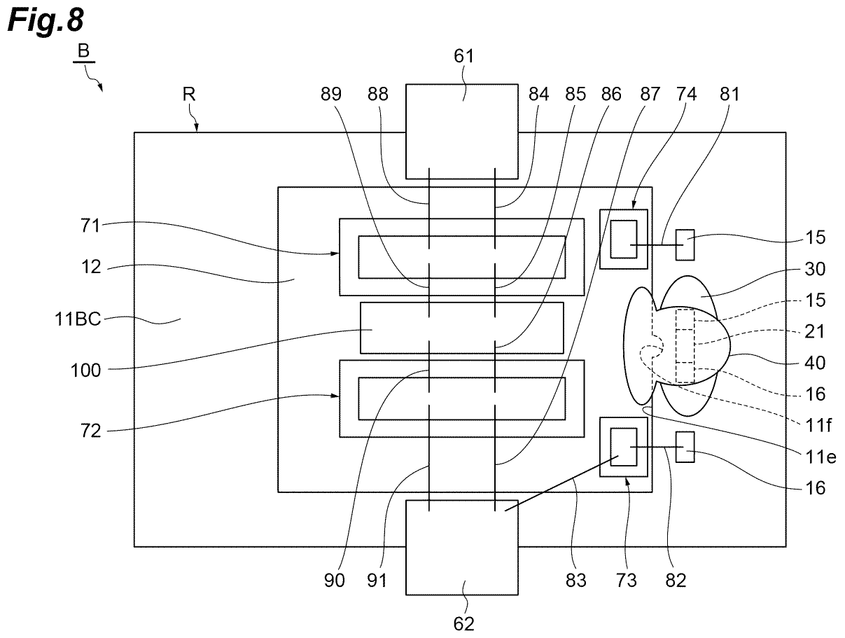

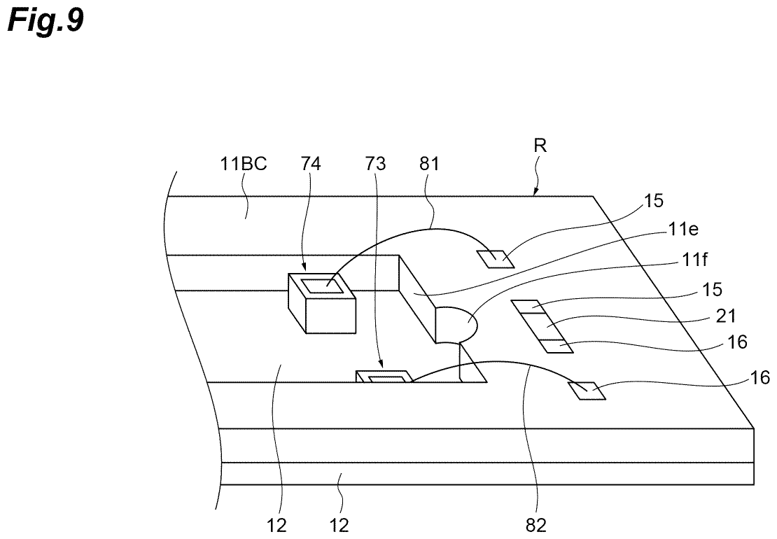

FIG. 8 is a plan view showing a semiconductor device B according to the first modification. FIG. 9 is a perspective view showing a part of semiconductor device B according to the first modification. In FIG. 9, electrically insulating film 30 or metal bonding material 40 are not shown. Semiconductor device B is different from semiconductor device A in the following points, and is the same as semiconductor device A in other points. Semiconductor device B includes a package R instead of package P. Package R includes a frame body 11BC instead of frame body 11. The other configuration of package R is the same as that of package P. In this modification, a half via 11f is provided at the center of surface Ile of frame body 11BC. Half via 11f has a semicircular shape in plan view (as viewed from the normal direction of surface 12a). A surface of half via 11f is plated with gold (Au). A portion of metal bonding material 40 between a portion in contact with electrically insulating film 30 and a portion in contact with stem 12 is accommodated in half via 11f.

In semiconductor device B having the above-described configuration, metal bonding material 40 can be more reliably guided to a desired position on stem 12 by half via 11f. Thus, metal bonding material 40 can be applied to a desired position on stem 12 with high accuracy.

### Second Modification

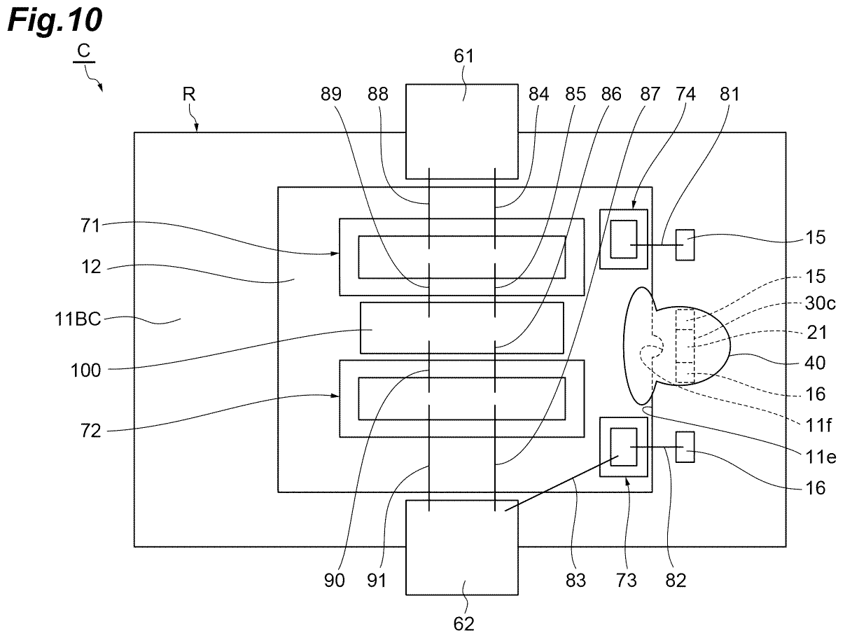

FIG. 10 is a plan view showing a semiconductor device C according to the second modification. Semiconductor device C is different from semiconductor device B in the following points, and is the same as semiconductor device B in the other points. In semiconductor device C, an electrically insulating film 30c (first electrically insulating film) is provided on frame body 11BC instead of electrically insulating film 30. Electrically insulating film 30c covers entire resistor 21. Electrically insulating film 30c is in contact with resistor 21. Electrically insulating film 30c has a rectangular shape in plan view. Electrically insulating film 30c is formed by solidifying a paste material. The material of electrically insulating film 30c is, for example, ceramic. Metal bonding material 40 is provided on electrically insulating film 30c and is in contact with entire electrically insulating film 30c.

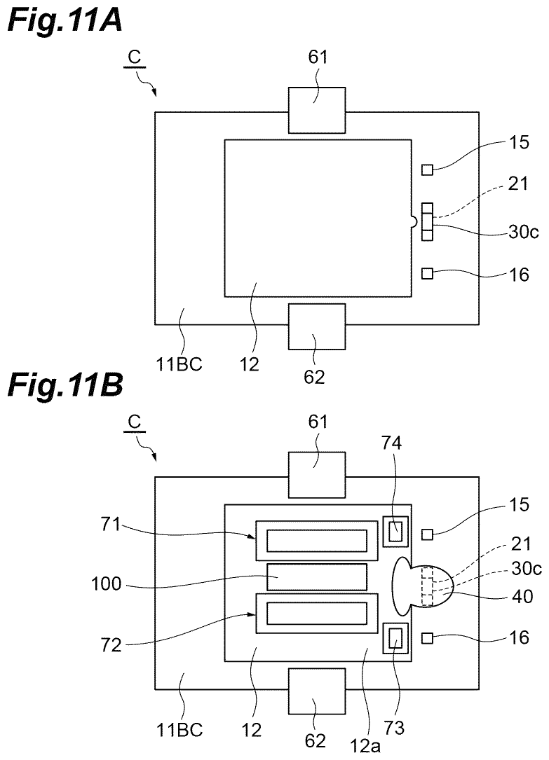

A method of manufacturing semiconductor device C according to the second modification of the present disclosure will be described with reference to FIGS. 11A and 11B. The manufacturing method of semiconductor device C is the same as the manufacturing method of semiconductor device A up to the process of pattern-printing of resistor 21 on frame body 11BC. As shown in FIG. 11A, after resistor 21 is provided between pattern 15 and pattern 16, a ceramic coat in a paste form which becomes electrically insulating film 30c is applied on resistor 21. The ceramic coat covers entire resistor 21. After the ceramic coat is applied, semiconductor device C is fired to solidify the ceramic coat, thereby forming electrically insulating film 30c. Thereafter, the lead frame (not shown) is cut off from the tie bar. Subsequently, as shown in FIG. 11B, metal bonding material 40 is dropped so as to be in contact with electrically insulating film 30c and stem 12. At the same time, metal bonding material 41 is applied to the surface on which semiconductor chip 100 and capacitors 71 to 74 are to be mounted. Thereafter, semiconductor chip 100 and capacitors 71 to 74 are mounted on surface 12a. The subsequent manufacturing method of semiconductor device C is the same as the manufacturing method of semiconductor device A.

In semiconductor device C having the above configuration, the insulating film can be locally formed even when electrically insulating film 30 is replaced with electrically insulating film 30c. In addition, since the ceramic generally has high heat resistance, the ceramic can withstand the heat from melted metal bonding material 40. Further, in the same process as the process of providing ceramic coat 10 on pattern 15 and pattern 16, electrically insulating film 30c may be provided on resistor 21. In that case, the number of processes can be reduced. Thus, the working efficiency in the manufacture of semiconductor device C is improved.

### Third Modification

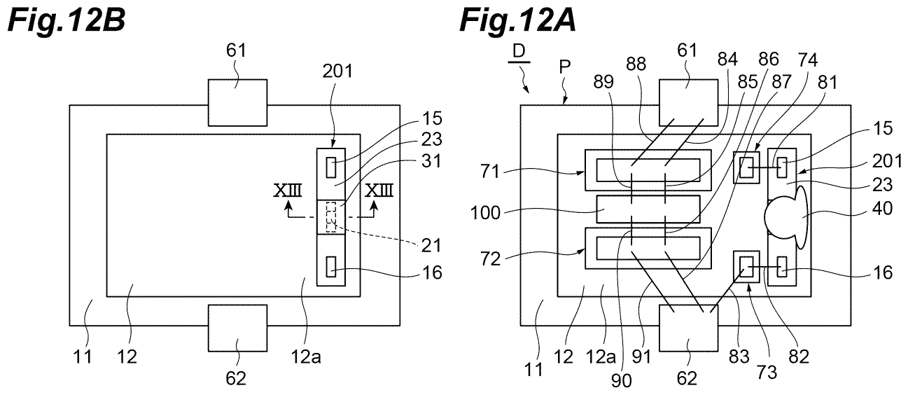

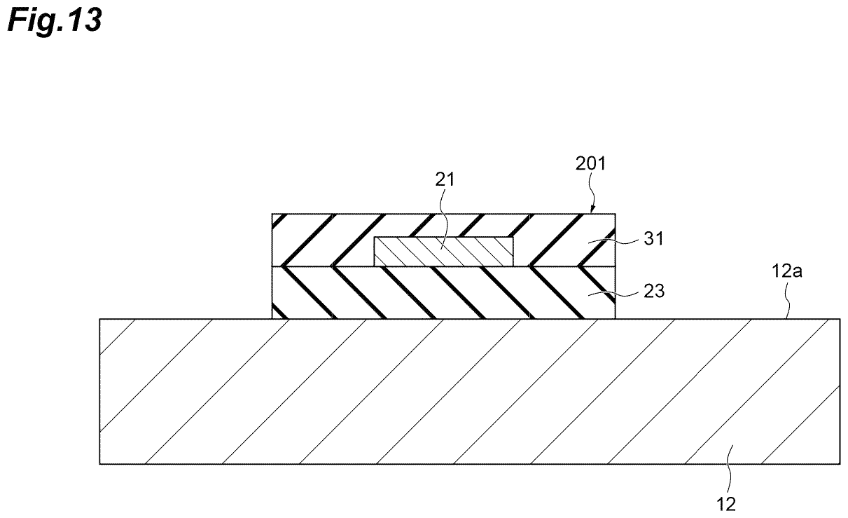

FIG. 12A is a plan view showing a semiconductor device D according to the third modification. FIG. 12B is a diagram of in semiconductor device D in which semiconductor chip 100, capacitors 71 to 74, and metal bonding material 40 are omitted. FIG. 13 is a cross-sectional view taken along line XIII-XIII shown in FIG. 12B. Semiconductor device D is different from semiconductor device A in the following points, and is the same as semiconductor device A in the other points. In semiconductor device D, resistor 21, pattern 15, and pattern 16 are provided in a portion that is not on frame body 11. That is, semiconductor device D includes a resistor component 201. Resistor component 201 includes a substrate 23, an insulator 31 (first electrically insulating film), resistor 21, pattern 15, and pattern 16. As shown in FIG. 12A, resistor component 201 is provided on the opposite side of semiconductor chip 100 with respect to capacitor 73 and capacitor 74. Resistor 21 is embedded in the center portion of resistor component 201, and pattern 15 and pattern 16 are exposed on the surfaces of both end portions of resistor component 201. Resistor component 201 has a rectangular shape in plan view. Substrate 23 is provided on surface 12a. A material of substrate 23 is, for example, ceramic such as alumina. As shown in FIG. 13, resistor 21 is provided on substrate 23 and is in contact with substrate 23. Insulator 31 is provided on substrate 23 and on resistor 21, and is in contact with substrate 23 and with resistor 21, and covers resistor 21. A material of insulator 31 is, for example, ceramic such as alumina. As shown in FIG. 12A, metal bonding material 40 is provided on insulator 31.

In semiconductor device D having the above-described configuration, resistor 21 is insulated from metal bonding material 40 by insulator 31 instead of electrically insulating film 30. Resistor component 201 may be assembled in advance. Thus, by incorporating resistor component 201 into semiconductor device D, the process of electrically insulating resistor 21 can be omitted. Thus, the working efficiency in the manufacture of semiconductor device D is improved.

### Fourth Modification

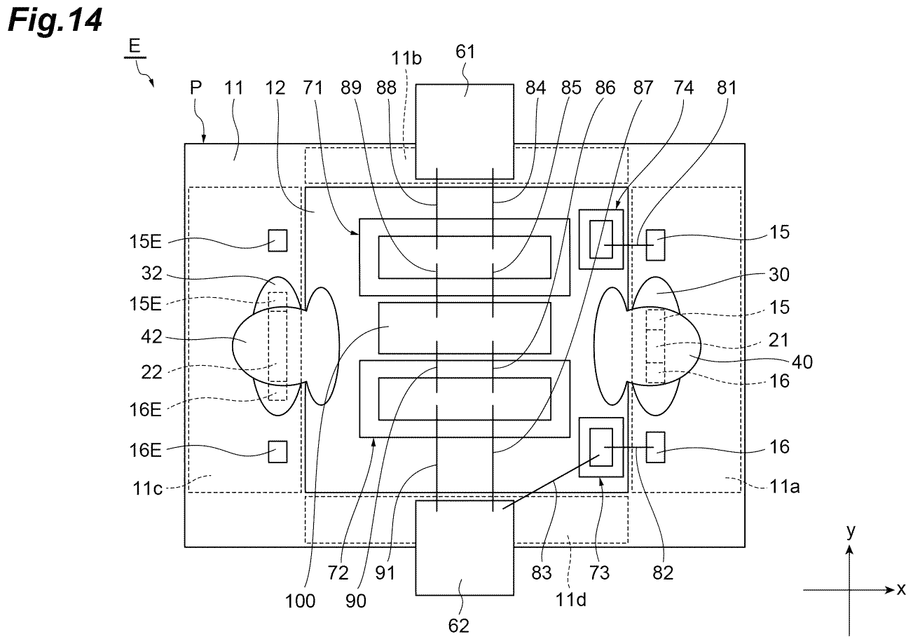

FIG. 14 is a plan view showing a semiconductor device E according to the fourth modification. Semiconductor device E is different from semiconductor device A in the following points, and is the same as semiconductor device A in the other points. Semiconductor device E further includes a resistor 22 (second resistor), a pattern 15E, and a pattern 16E. Resistor 22 is provided on the center portion of surface 11c, closer to the inner edge of frame body 11 than the outer edge of frame body 11, and in contact with surface 11c. Resistor 22 has a rectangular film shape. A material of resistor 22 is, for example, an alloy containing at least one conductor of silver (Ag), palladium (Pd), and platinum (Pt). An electrically insulating film 32 (second electrically insulating film) is provided on resistor 22. A metal bonding material 42 (second metal bonding material) is provided on electrically insulating film 32. Electrically insulating film 32 and metal bonding material 42 have the same configurations as those of electrically insulating film 30 and metal bonding material 40, respectively. Resistor 22 has a resistance value different from that of resistor 21. For example, a length of resistor 22 in the Y direction is different from a length of resistor 21 in the Y direction. Pattern 15E and pattern 16E are arranged along the Y direction on surface 11c. Pattern 15E and pattern 16E are provided on both sides of resistor 22 in the Y direction with resistor 22 interposed therebetween and are in contact with resistor 22.

In semiconductor device E having the above configuration, resistor 22 has the resistance value different from that of resistor 21. The circuit configuration can be easily changed by providing resistor 22 having the resistance value different from that of resistor 21 and changing the connection of the resistors in semiconductor device E.

### Fifth Modification

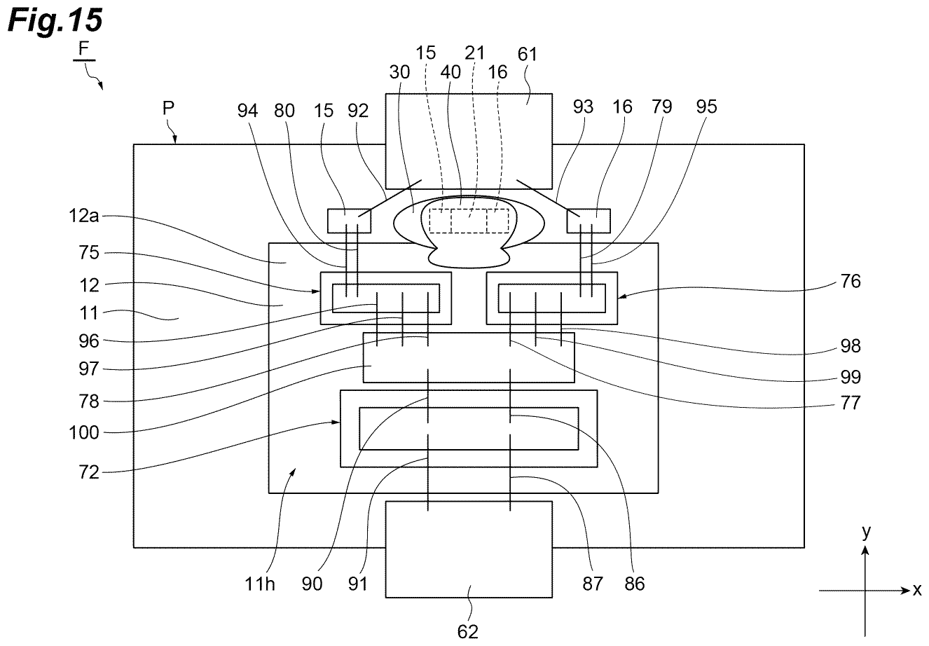

FIG. 15 is a plan view showing a semiconductor device F according to the fifth modification. Semiconductor device F is different from semiconductor device A in the following points, and is the same as semiconductor device A in the other points. Resistor 21, pattern 15, and pattern 16 of semiconductor device F are arranged in the x direction between terminal 61 and the inner edge of frame body 11 (that is, on surface 11b shown in FIG. 1). Pattern 16, resistor 21, and pattern 15 are arranged in this order. Resistor 21 of the present modification is a resistor for oscillation prevention. In addition, semiconductor device F includes a capacitor 75 and a capacitor 76 instead of capacitor 71. Semiconductor device F does not include capacitor 73 or capacitor 74. Capacitor 75 and capacitor 76 are arranged along the x direction. Capacitor 75 and capacitor 76 are provided on surface 12a between semiconductor chip 100 and terminal 61. In addition, semiconductor device F includes wires 77 to 80 and wires 92 to 99 instead of wires 81 to 85, wire 88, and wire 89. Wire 92 connects terminal 61 and pattern 15. Wire 93 connects terminal 61 and pattern 16. Wires 80 and 94 connect pattern 15 and capacitor 75. Wires 79 and 95 connect pattern 16 and capacitor 76. Wires 78, 96, and 97 connect capacitor 75 and semiconductor chip 100. Wires 77, 98, and 99 connect capacitor 76 and semiconductor chip 100.

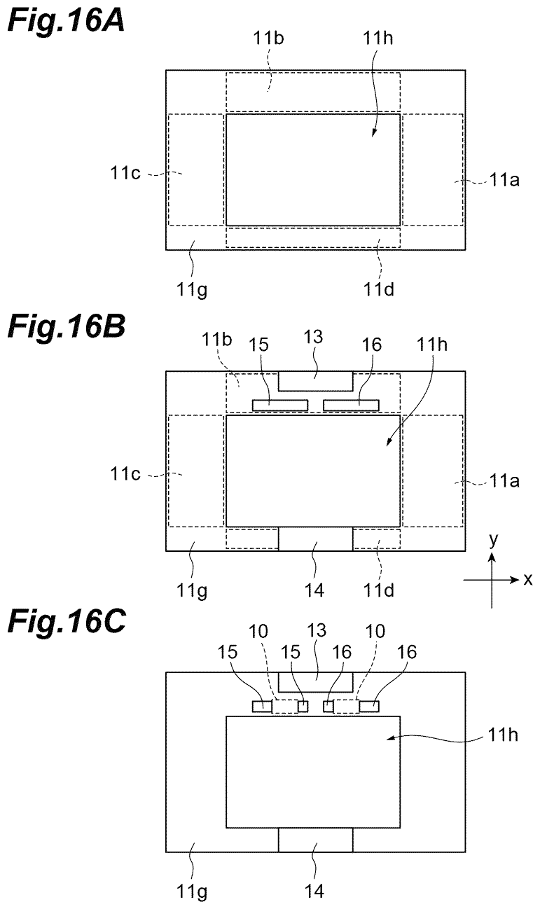

A method of manufacturing semiconductor device F according to the fifth modification of the present disclosure will be described with reference to FIGS. 16A, 16B, 16C, 17A, 17B, 17C, 18A, 18B, and 18C. First, frame body 11 having cavity 11h on the inside and formed of an insulator is prepared. As shown in FIG. 16A, cavity 11h is provided in the center portion of green sheet 11g made of ceramic before firing. Next, as shown in FIG. 16B, patterns 13 to 16 are provided on green sheet 11g by pattern printing. Pattern 13 is arranged on the center portion of surface 11b, and is arranged closer to the outer edge of green sheet 11g with respect to cavity 11h. Thereafter, as shown in FIG. 16C, ceramic coat 10 is applied to the center portion of pattern 15 and the center portion of pattern 16. At this time, only the end portions of patterns 15 and 16 are exposed. Thereafter, green sheet 11g and ceramic coat 10 are fired to form frame body 11.

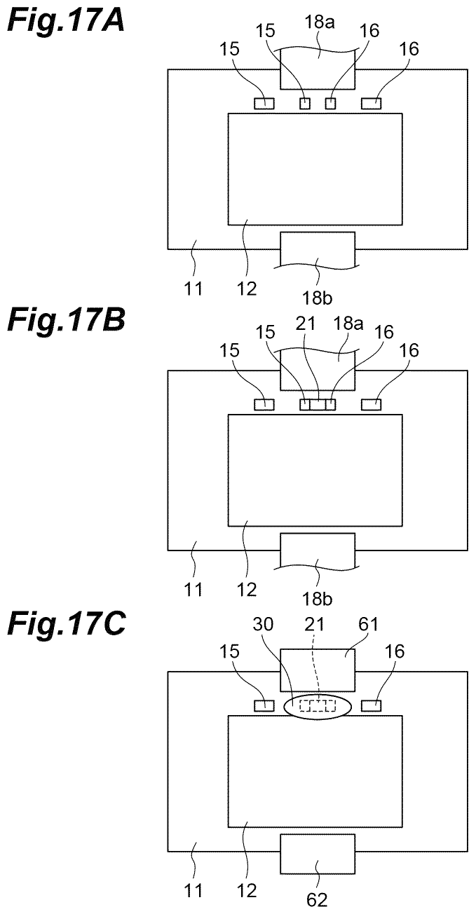

Next, a metal pattern (not shown) is formed on a rear surface of frame body 11. Thereafter, stem 12 is bonded to the rear surface of frame body 11. Subsequently, as shown in FIG. 17A, a lead frame including tie bars 18a and 18b is arranged on frame body 11. Thereafter, stem 12, pattern 15, pattern 16, tie bar 18a, and tie bar 18b are plated with gold (Au). Subsequently, as shown in FIG. 17B, a film for resistor 21 connected to pattern 15 and pattern 16 is formed between pattern 15 and pattern 16 on frame body 11, and the film is fired together with frame body 11 to form resistor 21. Thereafter, as shown in FIG. 17C, electrically insulating film 30 in contact with resistor 21 is formed on resistor 21. Electrically insulating film 30 is provided on resistor 21 by, for example, printing of glass coating so as to cover entire resistor 21. Thereafter, the glass coating is fired together with frame body 11 to form electrically insulating film 30. Thereafter, tie bar 18a and tie bar 18b are cut off from the main body of the lead frame. As a result, tie bar 18a becomes terminal 61, and tie bar 18b becomes terminal 62.

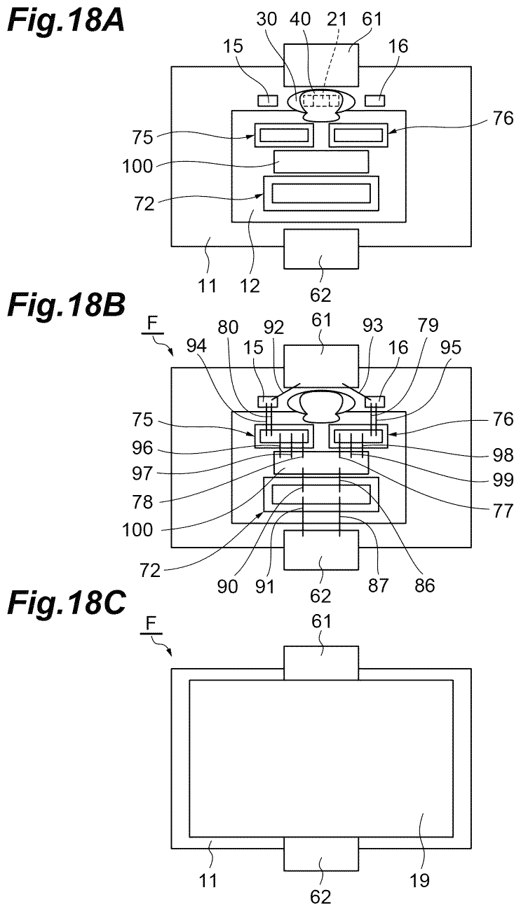

Next, metal bonding material 41 is applied to a region where semiconductor chip 100, capacitor 72, capacitor 75, and capacitor 76 are to be mounted, and at the same time, as shown in FIG. 18A, metal bonding material 40 is dropped so as to be in contact with electrically insulating film 30 and stem 12. Thereafter, semiconductor chip 100, capacitor 72, capacitor 75, and capacitor 76 are mounted on and fixed to stem 12. Subsequently, as shown in FIG. 18B, wires 77 to 80, wires 86 and 87, and wires 90 to 99 are provided. Finally, as shown in FIG. 18C, lid 19 is attached on frame body 11.

Semiconductor device F having the above configuration also provides the same effects as semiconductor device A. In addition, resistor 21 can be disposed at various positions. Semiconductor devices for various purposes can be obtained according to the arrangement of resistor 21 and the connection of the wires.

### Sixth Modification

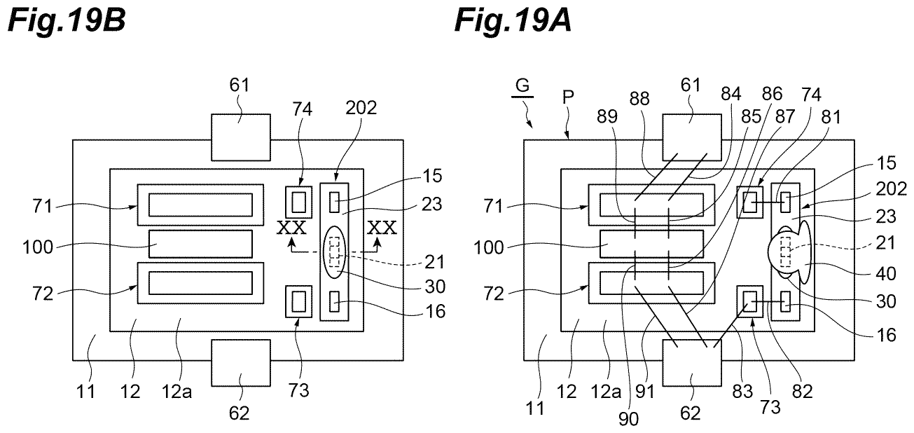

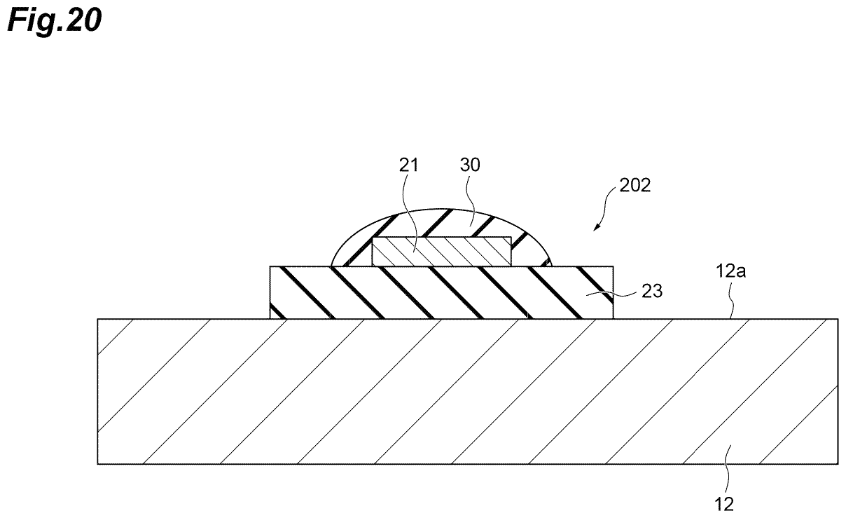

FIG. 19A is a plan view showing a semiconductor device G according to the sixth modification. FIG. 19B is a diagram of semiconductor device G in which metal bonding material 40 and the wire are omitted. FIG. 20 is a cross-sectional view taken along line XX-XX shown in FIG. 19B. Semiconductor device G is different from semiconductor device D in the following points, and is the same as semiconductor device D in the other points. Semiconductor device G includes a resistor component 202 instead of resistor component 201. Resistor component 202 includes substrate 23, electrically insulating film 30, resistor 21, pattern 15, and pattern 16. As shown in FIG. 19A, resistor component 202 is provided on the opposite side of semiconductor chip 100 with respect to capacitor 73 and capacitor 74. Resistor 21 is embedded in the center portion of resistor component 202, and pattern 15 and pattern 16 are exposed from both end portions of resistor component 202. Resistor component 202 has a rectangular shape in plan view. Resistor 21 is provided on substrate 23 and is in contact with substrate 23. Electrically insulating film 30 is provided on substrate 23 and on resistor 21, and covers entire resistor 21. Electrically insulating film 30 is in contact with substrate 23 and resistor 21. As shown in FIG. 19A, metal bonding material 40 is provided on electrically insulating film 30.

Semiconductor device G having the above configuration also provides the same effects as semiconductor device D.

Although the present invention has been described in detail based on the embodiments and modifications, the present invention is not limited to the embodiments and modifications described above, and can be modified without departing from the scope of the invention. For example, metal bonding material 40 is not limited to the above embodiments and modifications, and may cover entire electrically insulating film 30. In addition, electrically insulating film 30 is not limited to the above-described embodiments and modifications, and may cover only a part of resistor 21. In addition, in the above-described embodiments and modifications, the example in which one half via 11f is provided on surface 11e is shown, but a plurality of half vias 11f may be provided on surface 11e. In the above-described embodiments and modifications, the example in which resistor 21 is a resistor for low-frequency pass or for oscillation prevention is shown, but resistor 21 may be a resistor for an attenuator.

What is claimed is:

1. An electronic component comprising:
an insulator;
a first resistor provided on the insulator;
a first electrically insulating film provided on the first resistor to be in contact with the first resistor; and
a first metal bonding material provided on the first electrically insulating film to be in contact with the first electrically insulating film and be in contact with a heat sink.

2. The electronic component according to claim 1,
wherein the insulator is provided on the heat sink.

3. The electronic component according to claim 1,
wherein the first electrically insulating film contains at least one of glass and ceramic.

4. A semiconductor device in which the electronic component according to claim 1 is mounted on the heat sink, the semiconductor device comprising:
a semiconductor chip provided on the heat sink; and
a capacitor provided on the heat sink,
wherein the semiconductor chip is electrically connected to the capacitor and the first resistor through a wire.

5. The semiconductor device according to claim 4,
wherein the semiconductor chip is a transistor, and
wherein the first resistor is a resistor for a low-frequency pass or for oscillation prevention.

6. The semiconductor device according to claim 4,
wherein the semiconductor chip includes a silicon carbide substrate, and
wherein the first metal bonding material is a silver paste.

7. The semiconductor device according to claim 4, further comprising:
a second resistor provided on the insulator;
a second electrically insulating film provided on the second resistor to be in contact with the second resistor; and
a second metal bonding material provided on the second electrically insulating film to be in contact with the second electrically insulating film,
wherein the second resistor has a resistance value differing from a resistance value of the first resistor.

8. The semiconductor device according to claim 4,
wherein the insulator is a frame body provided on the heat sink and having a cavity inside the frame body,
wherein the semiconductor chip and the capacitor are disposed inside the cavity, and
wherein the frame body and the heat sink are members constituting a package of the semiconductor device.

9. The semiconductor device according to claim 8,
wherein the frame body has a side surface on an inner side of the cavity,
wherein the side surface is provided with a half via, and
wherein, in the first metal bonding material, a portion between a portion in contact with the first electrically insulating film and a portion in contact with the heat sink is accommodated in the half via.

10. A method of manufacturing a semiconductor device, the method comprising:
preparing a frame body having a cavity inside the frame body and constituted by an insulator, the frame body being bonded on a heat sink;
forming a resistor on the frame body;
forming an electrically insulating film on the resistor to be in contact with the resistor; and
dropping a metal bonding material to be in contact with the electrically insulating film and the heat sink.

11. The method of manufacturing the semiconductor device according to claim 10, the method further comprising:
mounting a semiconductor chip and a capacitor on the heat sink after the dropping,
wherein, in the dropping, the metal bonding material is applied to a region on the heat sink at which the semiconductor chip and the capacitor are to be mounted.
